(19) United States
(12) Patent Application Publication
(10) Pub. No.: US 2003/0040165 A1
(43) Pub. Date: Feb. 27, 2003

(54) Method for rounding bottom corner in LOCOS process by using high density plasma poly etcher

(76) Inventor: Chun-Hung Lee, ChungLi City (TW)

Correspondence Address: SUPREME PATENT SERVICES, POST OFFICE BOX 2339, SARATOGA, CA, 95070, US

(21) Appl. No.: 09/934,727

(22) Filed: Aug. 22, 2001

(51) Int. Cl. H01L 21/76; H01L 21/302; H01L 21/461

(52) U.S. Cl. 438/444; 438/719; 438/710

(57) ABSTRACT

A method for rounding bottom corner in LOCOS process by using high density plasma poly etcher comprising the steps of preparing a Si substrate, forming sequentially on the Si substrate with a pad oxide layer and a Si₃N₄ layer, using a high density plasma poly etcher (HDPPE) with a gas of CF₄/Ar or CH₄/He to etch the pad oxide layer and the Si₃N₄ layer to form an opening and a recess in the Si substrate and to round bottom corners of the recess.

### FIELD OF THE INVENTION

The present invention relates to a method for increasing rounding effect in the bottom corner in the LOSOC process, and more particularly to a method to increase rounding to the bottom corner in the LOCOS process by using high density plasma poly etcher (HDPPE).

### BACKGROUND OF THE INVENTION

In manufacturing electronic element and/or integrated circuit, several films such as heat oxide layer, dielectric layer, etc. are used to isolate the electronic elements from each other. One of the films is heat oxide, which is the field oxide, and is a crucial manufacturing step to isolate oxide layer. This kind of isolation is able to use the SiO₂ as the medium. A conventional method uses LOCOS isolation to accomplish the desired goal. The conventional method causes Bird's Beak, as shown in FIG. 1, around the field oxide and affects the smoothness, reduces density of the wafer, which brings a lot of inconvenience in the manufacturing process. Thus, STI (shallow trench isolation) technique is taking place gradually. However, many manufacturers still adopt the recess LOCOS technique in semiconductor.

According to the existed method, the round bottom corner at the recess is achieved by the oxide etcher or the recess LOCOS etcher. However, the depth uniformity of the etching depth is more than 10% than the standard value, which is far more too much in the increasing demand in the precision of semiconductor industry.

Although, in the STI technique, the HDPPE is also applied in the etching process, in the recess smaller than 500 Å(Angstrom), the round bottom corner still can not be achieved successfully.

To overcome the shortcomings, the present invention intends to provide an improved method for rounding bottom corner in LOCOS process by using high density plasma poly etcher.

### SUMMARY OF THE INVENTION

The primary objective of the invention is to provide a method for rounding bottom corner in LOCOS process by using high density plasma poly etcher. The method of the invention has the following steps. First, it is necessary to prepare a substrate. The second step is to form sequentially on the substrate with a pad oxide layer and a dielectric layer. The third step is to use a high density plasma poly etcher (HDPPE) with a gas to etch the pad oxide layer and the dielectric layer to form an opening and a recess in the substrate, wherein bottom corners of the recess are rounded.

Other objects, advantages and novel features of the invention will become more apparent from the following detailed description when taken in conjunction with the accompanying drawings.

### BRIEF DESCRIPTION OF THE DRAWINGS

FIG. 1 is a schematic view of a conventional method, which causes Bird's beak around edge of the field oxide;

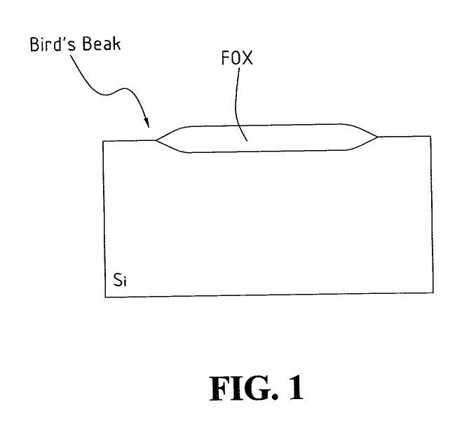

FIGS. 2A to 2B are schematic views of the method in accordance with the present invention, wherein CF₄/Ar or CH₄/He is applied to have the round bottom corner;

FIGS. 3A to 3B are schematic views of another preferred embodiment of the method of the present invention.

### DETAILED DESCRIPTION OF THE INVENTION

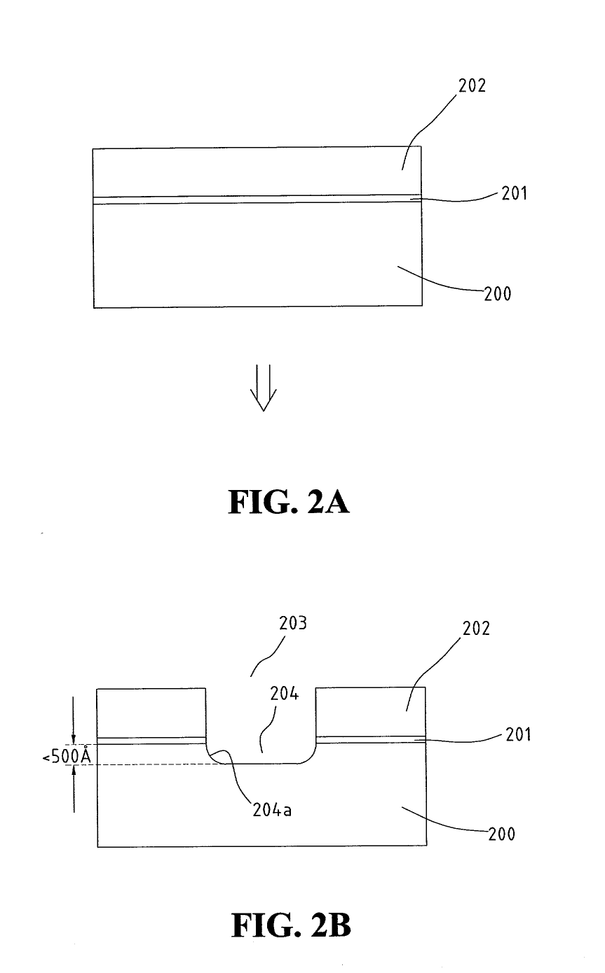

With reference to FIGS. 2A to 2B, a method for rounding bottom corner in LOCOS process by using high density plasma poly etcher is disclosed, which is able to have a better depth uniformity (less than 5%) in the etching recess and the high density plasma poly etcher is able to be applied in-situ to the recess in the Si-substrate to obtain the round bottom corner. The method includes the steps of preparing a Si substrate 200; forming sequentially on the Si substrate 200 with a pad oxide layer 201 and a Si₃N₄ layer 202, wherein the pad oxide layer 201 may be a SiON layer; using a high density plasma poly etcher (HDPPE) with a gas of CF₄/Ar or CH₄/He to etch the pad oxide layer 201 and the Si₃N₄ layer 202 to form an opening 203 and a recess 204 in the Si substrate 200, wherein the pressure of the CF₄/Ar or CH₄/He is around 50˜70 mT and the HDPPE is applied in-situ etch.

It is to be noted that when the HDPPE is applied, bottom corners 204a of the recess 204 is rounded. Furthermore, the cathode temperature of the HDPPE is about 50˜70° C., the chamber wall temperature is about 60˜80° C., the bottom power (bias power) is 40˜60 W and the source power is 500˜1000 W.

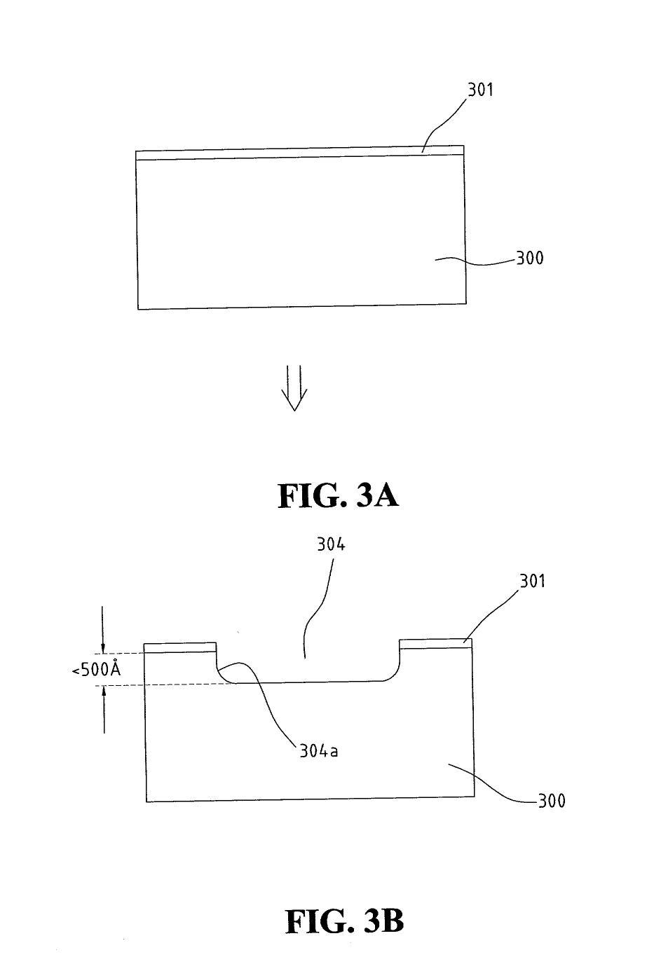

With reference to FIGS. 3A and 3B, another preferred embodiment of the present invention is disclosed, wherein the steps include: preparing a Si substrate 300; forming on the Si substrate 300 with a pad oxide layer 301; using a high density plasma poly etcher (HDPPE) with a gas of CF₄/Ar or CH₄/He with pressure of 50˜70 mT to etch the pad oxide layer 301 to form a silicon recess 304 in the Si substrate 300 and round the bottom corner 304a.

It is to be noted that when the HDPPE is applied, the cathode temperature of the HDPPE is about 50˜70° C., the chamber wall temperature is about 60˜80° C., the bottom power (bias power) is 40˜60 W and the source power is 500˜1000 W.

With such a method as foregoing described, the depth uniformity of the recess in the substrate is able to reach less than 5% when compared with the standard value and the disadvantage of controlling the depth uniformity less than 500 Å(Angstrom) is overcome.

Even though numerous characteristics and advantages of the present invention have been set forth in the foregoing description, together with details of the structure and function of the invention, the disclosure is illustrative only, and changes may be made in detail, especially in matters of shape, size, and arrangement ol parts within the principles of the invention to the full extent indicated by the broad general meaning of the terms in which the appended claims are expressed.

What is claimed is:

1. A method for rounding bottom corner in LOCOS process by using high density plasma poly etcher comprising the steps of:
a. preparing a substrate;
b. forming sequentially on the substrate with a pad oxide layer and a dielectric layer;
c. using a high density plasma poly etcher (HDPPE) with a gas to etch the pad oxide layer and the dielectric layer to form an opening and a recess in the substrate, wherein bottom corners of the recess are rounded.

2. The method as claimed in claim 1, wherein the gas is CF₄/Ar.

3. The method as claimed in claim 1, wherein the gas is CH₄/He.

4. The method as claimed in claim 2, wherein pressure of the CF₄/Ar is around 50˜70 mT and the HDPPE is applied in-situ etch.

5. The method as claimed in claim 3, wherein pressure of the CH₄/He is around 50˜70 mT and the HDPPE is applied in-situ etch.

6. The method as claimed in claim 1, wherein the dielectric layer is Si₃N₄.

7. The method as claimed in claim 1, wherein a cathode temperature of the HDPPE is about 50˜70° C.

8. The method as claimed in claim 1, wherein a chamber wall temperature is about 60˜80° C.

9. The method as claimed in claim 1, wherein a bottom power (bias power) is 40˜60 W.

10. The method as claimed in claim 1, wherein a source power is 500˜1000 W.

11. The method as claimed in claim 1, wherein the substrate is made of Si.

12. A method for rounding bottom corner of silicon recess comprising the steps of:
a. preparing a substrate;
b. forming on the substrate with a pad oxide layer;
c. using a high density plasma poly etcher (HDPPE) with a gas to form a silicon recess in the substrate and round the bottom corner.

13. The method as claimed in claim 12, wherein the gas is CF₄/Ar.

14. The method as claimed in claim 12, wherein the gas is CH₄/He.

15. The method as claimed in claim 13, wherein pressure of the CF₄/Ar is around 50˜70 mT and the HDPPE is applied in-situ etch.

16. The method as claimed in claim 14, wherein pressure of the CH₄/He is around 50˜70 mT and the HDPPE is applied in-situ etch.

17. The method as claimed in claim 12, wherein a cathode temperature of the HDPPE is about 50˜70° C.

18. The method as claimed in claim 12, wherein a chamber wall temperature is about 60˜80° C.

19. The method as claimed in claim 12, wherein a bottom power (bias power) is 40˜60 W.

20. The method as claimed in claim 12, wherein a source power is 500˜1000 W.
